(19) United States
(12) Patent Application Publication
(10) Pub. No.: US 2024/0423063 A1
(43) Pub. Date: Dec. 19, 2024

(54) DISPLAY DEVICE

(71) Applicant: Samsung Display Co., LTD., Yongin-si (KR)

(72) Inventors: Youn Joeng GOH, Yongin-si (KR); Ki Cheol SONG, Yongin-si (KR); Sun Je PARK, Yongin-si (KR); Young Sang PARK, Yongin-si (KR)

(21) Appl. No.: 18/443,490

(22) Filed: Feb. 16, 2024

(30) Foreign Application Priority Data
Jun. 14, 2023 (KR) 10-2023-0076428

(51) Int. Cl. H10K 59/80; H10K 102/00

(52) U.S. Cl. CPC H10K 59/872; H10K 2102/311; H10K 2102/351

(57) ABSTRACT

A display device includes a display panel including a surface disposed at a front thereof, and a front stacked structure disposed on the surface of the display panel, where the front stacked structure includes a cover window and a first composite member disposed on the cover window, the first composite member includes a base layer and a resin layer disposed on the base layer, and the first composite member has a coefficient of thermal expansion of about 20 parts per million per degrees Celsius (ppm/° C.) to about 45 ppm/° C. in a temperature range of about −40° C. to about 60° C.

### DISPLAY DEVICE

This application claims priority to Korean Patent Application No. 10-2023-0076428,filed on Jun. 14, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

Electronic devices such as smartphones, tablet personal computers, digital cameras, laptop computers, navigation devices, and smart televisions that provide images to users include display devices for displaying the images. Recently, foldable display devices are attracting a lot of attention. The foldable display devices have advantages of both smartphones and tablet personal computers because they may have good portability and wide screens.

In the foldable display device, a plurality of stacked structures is stacked and coupled to each other, and a coupling member is used between the respective stacked structures. The coupling member may serve to protect the stacked structures of the display device from external impact while coupling the respective stacked structures to each other. Accordingly, the coupling member is desired to have impact resistance characteristics so as to be capable of protecting the stacked structures of the display device from the external impact.

### SUMMARY

Features of the disclosure provide a display device capable of improving impact resistance characteristics.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a display device includes a display panel including a surface disposed at a front thereof, and a front stacked structure disposed on the surface of the display panel, where the front stacked structure includes a cover window and a first composite member disposed on the cover window, the first composite member includes a base layer and a resin layer disposed on the base layer, and the first composite member has a coefficient of thermal expansion of about 20 parts per million per degrees Celsius (ppm/° C.) to about 45 ppm/° C. in a temperature range of about −40° C. to about 60° C.

In an embodiment, the base layer may have a thickness of about 65 micrometer (μm) to about 75 μm.

In an embodiment, the resin layer may include any one of a silicone-based resin, an acrylate-based resin, and a urethane-based resin.

In an embodiment, the silicone-based resin may include a siloxane-based resin.

In an embodiment, the resin layer may have a thickness of about 20 μm to about 35 μm.

In an embodiment, the first composite member may have a storage modulus of about 2.7 gigapascals (GPa) to about 2.9 GPa at about 25° C.

In an embodiment, the first composite member may have a loss modulus of about 0.07 GPa to about 0.09 GPa at about 25° C.

In an embodiment, the first composite member may have a loss factor of about 0.024 to about 0.033 at about 25° C.

In an embodiment, the resin layer may be disposed between the cover window and the base layer and couple the cover window and the base layer to each other.

In an embodiment, the front stacked structure may further include an impact absorbing layer disposed between the display panel and the cover window, a first coupling member disposed between the cover window and the impact absorbing layer, and a second coupling member disposed between the impact absorbing layer and the display panel.

In an embodiment, the display panel may include an opposite surface disposed at a rear thereof, the display device may further include a rear stacked structure disposed on the opposite surface of the display panel, and the rear stacked structure may include a polymer film layer disposed behind the display panel, a cushion layer disposed behind the polymer film layer, and a plate disposed behind the cushion layer.

In an embodiment of the disclosure, a display device includes a display panel

including a surface disposed at a front thereof, and a front stacked structure disposed on the surface of the display panel, where the front stacked structure includes a cover window, a first composite member disposed on the cover window, and a second composite member disposed between the cover window and the display panel, each of the first composite member and the second composite member includes a base layer and a resin layer disposed on the base layer, and each of the first composite member and the second composite member has a storage modulus of about 2.7 GPa to about 2.9 GPa at about 25° C.

In an embodiment, the base layer may have a thickness of about 65 μm to about 75 μm.

In an embodiment, the resin layer may include any one of a silicone-based resin, an acrylate-based resin, and a urethane-based resin.

In an embodiment, the silicone-based resin may include a siloxane-based resin.

In an embodiment, the resin layer may have a thickness of about 20 μm to about 35 μm.

In an embodiment, each of the first composite member and the second composite member may have a coefficient of thermal expansion of about 20 ppm/° C. to about 45 ppm/° C. in a temperature range of about −40° C. to about 60° C.

In an embodiment, each of the first composite member and the second composite member may have a loss modulus of about 0.07 GPa to about 0.09 GPa at about 25° C. In an embodiment, each of the first composite member and the second composite

member may have a loss factor of about 0.024 to about 0.033 at about 25° C.

In an embodiment, the resin layer of the first composite member may be disposed between the cover window and the base layer of the first composite member, and the resin layer of the second composite member may be disposed between the display panel and the base layer of the second composite member.

A display device in an embodiment may improve impact resistance characteristics of the display device and relieve stress when the display device is folded, by including a composite member having physical properties such as a coefficient of thermal expansion, a storage modulus, a loss modulus, and a loss factor suitable for a foldable display device.

The effects of the disclosure are not limited to the aforementioned effects, and various other effects are included in the specification.

### BRIEF DESCRIPTION OF THE DRAWINGS

The above and other features and features of the disclosure will become more apparent by describing in detail embodiments thereof with reference to the attached drawings, in which:

FIG. 1 is a perspective view illustrating an embodiment of an unfolded state of a display device;

FIG. 2 is a perspective view illustrating an embodiment of a folded state of the display device;

FIG. 3 is a cross-sectional view illustrating an embodiment of the unfolded state of the display device;

FIG. 4 is a cross-sectional view illustrating an embodiment of the folded state of the display device;

FIG. 5 is a cross-sectional view of an embodiment of a display panel;

FIG. 6 is a cross-sectional view illustrating an embodiment of a first composite member;

FIG. 7 is a cross-sectional view of an embodiment of a display device;

FIG. 8 is a cross-sectional view of an embodiment of a display device;

FIGS. 9 to 11 are cross-sectional views illustrating an embodiment of processes of a method of manufacturing the display device; and

FIG. 12 is a chart illustrating pen drop test results of display device samples according to Experimental Example 1.

### DETAILED DESCRIPTION

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Hereinafter, embodiments will be described with reference to the accompanying drawings.

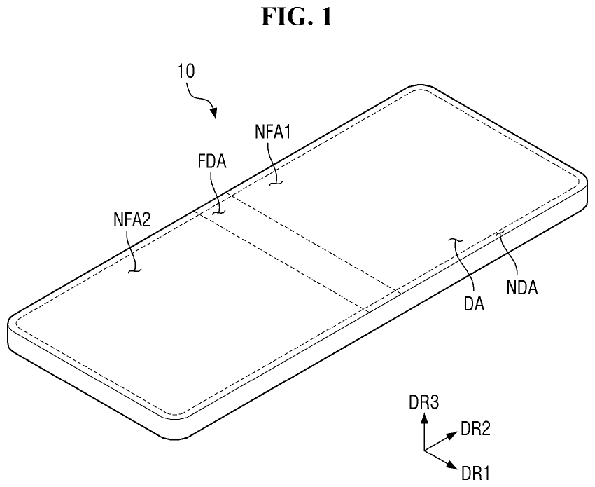

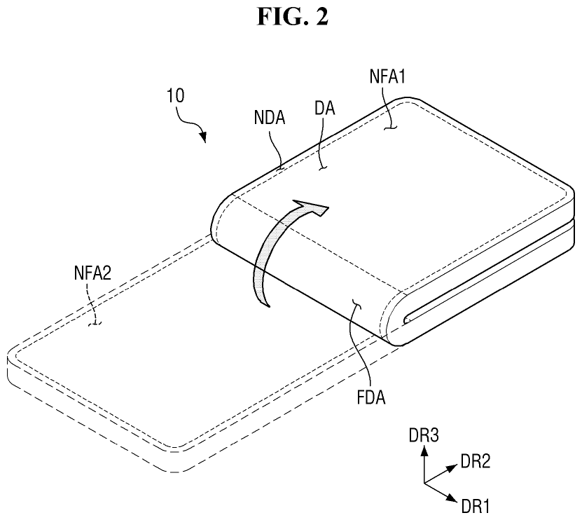

FIG. 1 is a perspective view illustrating an embodiment of an unfolded state of a display device. FIG. 2 is a perspective view illustrating an embodiment of a folded state of the display device.

Referring to FIG. 1, a display device 10 in an embodiment may be a foldable display

device. It will be mainly described that the display device 10 is applied to smartphones, but the disclosure is not limited thereto. In an embodiment, the display device 10 in embodiments of the disclosure may be applied to mobile phones, tablet personal computers, personal digital assistants (“PDAs”), portable multimedia players (“PMPs”), televisions, game machines, wrist watch-type electronic devices, head-mounted displays, monitors of personal computers, laptop computers, vehicle navigation devices, vehicle instrument boards, digital cameras, camcorders, external billboards, electric signs, medical devices, inspection devices, various home appliances such as refrigerators and washing machines, or Internet of Things (“IoT”) devices, in addition to the smartphones, for example. Hereinafter, illustrative embodiments will be described with reference to the accompanying drawings.

In FIGS. 1 and 2, a first direction DR1 is a direction parallel to one side of the display device 10 in a plan view, and may be a transverse direction of the display device 10, for example. A second direction DR2 is a direction parallel to the other side (opposite side) of the display device 10 in contact with one side of the display device 10 in a plan view, and may be a longitudinal direction of the display device 10. A third direction DR3 may be a thickness direction of the display device 10.

In an embodiment, the display device 10 may have a quadrangular shape, e.g., rectangular shape in a plan view. The display device 10 may have a rectangular shape with vertical corners or a rectangular shape with rounded corners in a plan view. The display device 10 may include two short sides disposed in the first direction DR1 and two long sides disposed in the second direction DR2 in a plan view.

The display device 10 includes a display area DA and a non-display area NDA. In a plan view, a shape of the display area DA may correspond to the shape of the display device 10. In an embodiment, when the display device 10 has the quadrangular shape, e.g., rectangular shape in a plan view, the display area DA may also have a quadrangular shape, e.g., rectangular shape, for example.

The display area DA may be an area displaying an image by including a plurality of pixels. The plurality of pixels may be arranged in a matrix direction. The plurality of pixels may have a rectangular shape, a rhombic shape, or a square shape in a plan view, but are not limited thereto. In an embodiment, the plurality of pixels may have other quadrangular shapes other than the rectangular shape, the rhombic shape, or the square shape, other polygonal shapes other than a quadrangular shape, a circular shape, or an elliptical shape in a plan view, for example.

The non-display area NDA may be an area that does not display an image because it does not include pixels. The non-display area NDA may be disposed around the display area DA. The non-display area NDA may be disposed to surround the display area DA as illustrated in FIGS. 1 and 2, but is not limited thereto. The display area DA may be partially surrounded by the non-display area NDA.

In an embodiment, the display device 10 may be maintained in both the folded state and the unfolded state. The display device 10 may be folded in an in-folding manner in which the display area DA is disposed inside as illustrated in FIG. 2. When the display device 10 is folded in the in-folding manner, upper surfaces of the display device 10 may be disposed to face each other. In another embodiment, the display device 10 may be folded in an out-folding manner in which the display area DA is disposed outside. When the display device 10 is folded in the out-folding manner, lower surfaces of the display device 10 may be disposed to face each other.

In an embodiment, the display device 10 may be a foldable device. The term “foldable device” as used herein is a device that may be folded, and is used as the meaning including not only a folded device, but also a device that may have both a folded state and an unfolded state. In addition, folding typically includes folding at an angle of about 180°, but is not limited thereto, and when a folding angle exceeds about 180° or is less than about 180°, e.g., about 90° or more and less than about 180° or about 120° or more and less than about 180°, it may be understood that the display device is folded. In addition, when the display device is in a bent state out of an unfolded state even though it is not completely folded, it may be also referred to as the folded state. In an embodiment, even though the display device is bent at an angle of 90° or less, as long as a maximum folding angle is 90° or more, it may be expressed that the display device is in the folded state in order to be distinguished from the unfolded state, for example. A radius of curvature of the display device when being folded may be about 5 millimeter (mm) or less, may be preferably in the range of about 1 mm to about 2 mm or may be about 1.5 mm, but is not limited thereto.

In an embodiment, the display device 10 may include a folding area FDA, a first non-folding area NFA1, and a second non-folding area NFA2. The folding area FDA may be an area in which the display device 10 is folded, and the first non-folding area NFA1 and the second non-folding area NFA2 may be areas in which the display device 10 is not folded.

The first non-folding area NFA1 may be disposed on one side, e.g., the upper side of the folding area FDA. The second non-folding area NFA2 may be disposed on the other side, e.g., the lower side of the folding area FDA. The folding area FDA may be an area curved with a predetermined curvature.

In an embodiment, the folding area FDA of the display device 10 may be determined at a predetermined position. The number of folding areas FDA determined at a predetermined position in the display device 10 may be one or two or more. In another embodiment, a position of the folding area FDA is not specified in the display device 10, and may be freely set in various areas.

In an embodiment, the display device 10 may be folded in the second direction DR2. For this reason, a length of the display device 10 in the first direction DR1 may be reduced by approximately half, and thus, a user may conveniently carry the display device 10.

In an embodiment, a direction in which the display device 10 is folded is not limited to the second direction DR2. In an embodiment, the display device 10 may be folded in the first direction DR1, for example. In this case, a length of the display device 10 in the first direction DR1 may be reduced by approximately half.

It has been illustrated in FIGS. 1 and 2 that each of the display area DA and the non-display area NDA overlaps the folding area FDA, the first non-folding area NFA1, and the second non-folding area NFA2, but the disclosure is not limited thereto. In an embodiment, each of the display area DA and the non-display area NDA may overlap at least one of the folding area FDA, the first non-folding area NFA1, and the second non-folding area NFA2, for example.

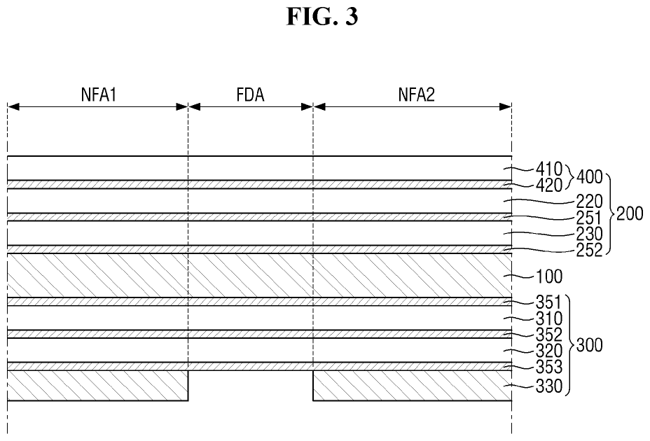

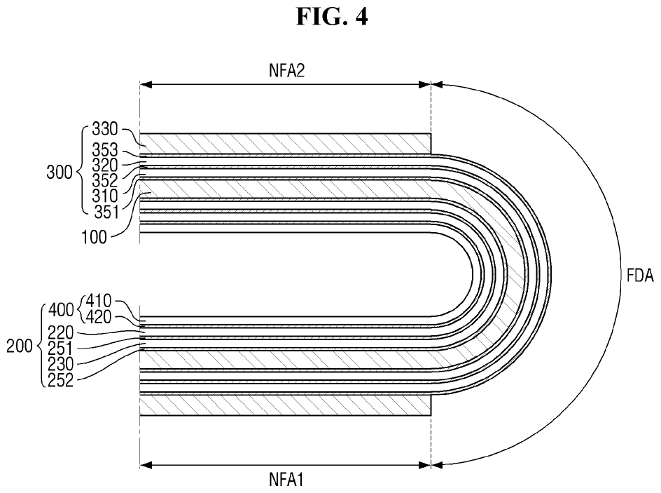

FIG. 3 is a cross-sectional view illustrating an embodiment of the unfolded state of the display device. FIG. 4 is a cross-sectional view illustrating an embodiment of the folded state of the display device.

Referring to FIGS. 3 and 4, the display device 10 may include a display panel 100,

a front stacked structure 200 stacked in front of the display panel 100, and a rear stacked structure 300 stacked behind the display panel 100. The respective stacked structures 200 and 300 may include one or more coupling members 251 and 252 and 351 to 353. Here, the front of the display panel 100 refers to a direction in which the display panel 100 displays a screen, and the rear of the display panel 100 refers to a direction opposite to the front. One surface of the display panel 100 is disposed at the front, and the other surface (opposite surface) of the display panel 100 is disposed at the rear.

The display panel 100 is a panel that displays a screen or an image, and embodiments of the display panel 100 may include not only a self-light-emitting display panel such as an organic light-emitting display panel (“OLED”), an inorganic light-emitting display panel (“inorganic EL”), a quantum dot light-emitting display panel (“QED”), a micro LED display panel (“micro-LED”), a nano LED display panel (“nano-LED”), a plasma display panel (“PDP”), a field emission display panel (“FED”), and a cathode ray display panel (“CRT”), but also a light-receiving display panel such as a liquid crystal display panel (“LCD”) and an electrophoretic display panel (“EPD”). Hereinafter, an organic light-emitting display panel will be described in an embodiment of the display panel 100, and unless the organic light-emitting display panel does not need to be specially distinguished from the display panel, the organic light-emitting display panel applied to an embodiment will be simply abbreviated as the display panel 100. However, an embodiment is not limited to the organic light-emitting display panel, and other display panels 100 described above or known in the present technical field may be applied within the scope of the technical spirit.

The display panel 100 may further include a touch member. The touch member may be provided as a separate panel or film from the display panel 100 and attached onto the display panel 100 or may be provided in the form of a touch layer inside the display panel 100. In the following embodiments, a case where the touch member is provided inside the display panel 100 and included in the display panel 100 will be described by way of example, but the disclosure is not limited thereto.

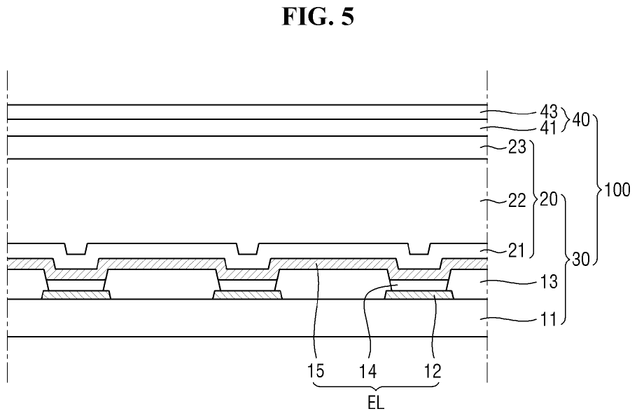

FIG. 5 is a cross-sectional view of an embodiment of a display panel.

Referring to FIG. 5, the display device 10 in an embodiment may include the display panel 100. The display panel 100 may include a base substrate 11, first electrodes 12, a pixel defining layer 13, light-emitting layers 14, a second electrode 15, and an encapsulation layer 20.

The base substrate 11 may be an insulating substrate. The base substrate 11 may be flexible and may include a polymer material having flexibility. Here, the polymer material may be polyimide (“PI”), polyethersulphone (“PES”), polyacrylate (“PA”), polyarylate (“PAR”), polyetherimide (“PEI”), polyethylene naphthalate (“PEN”), polyethylene terepthalate (“PET”), polyphenylene sulfide (“PPS”), polyallylate, polycarbonate (“PC”), cellulose triacetate (“CAT”), cellulose acetate propionate (“CAP”), or combinations thereof. The first electrodes 12 may be disposed on the base substrate 11. In an embodiment,

the first electrode 12 may be an anode electrode. Although not illustrated in FIG. 5, a plurality of components may be further disposed between the base substrate 11 and the first electrode 12. The plurality of components may include a buffer layer, a plurality of conductive lines, an insulating layer, a plurality of thin film transistors, or the like, in an embodiment.

The pixel defining layer 13 may be disposed on the first electrodes 12. The pixel defining layer 13 may include openings exposing at least portions of the first electrodes 12.

The light-emitting layers 14 may be disposed on the first electrodes 12. In an embodiment, the light-emitting layer 14 may emit one of red light, green light, and blue light. A wavelength of the red light may be about 620 nm to about 750 nm, and a wavelength of the green light may be about 495 nm to about 570 nm. In addition, a wavelength of the blue light may be about 450 nm to about 495 nm. The light-emitting layer 14 may be formed as a single layer. In an alternative embodiment, the light-emitting layer 14 may have a structure in which a plurality of organic light-emitting layers is stacked, e.g., a tandem structure. In another embodiment, the light-emitting layer 14 may emit white light. When the light-emitting layer 14 emits the white light, the light-emitting layer 14 may have a form in which a red organic light-emitting layer, a green organic light-emitting layer, and a blue organic light-emitting layer are stacked.

The second electrode 15 may be disposed on the light-emitting layers 14 and the pixel defining layer 13. The second electrode 15 may be entirely formed on the light-emitting layers 14 and the pixel defining layer 13 in an embodiment. In some embodiments, the second electrode 15 may be a cathode electrode.

The first electrode 12, the second electrode 15, and the light-emitting layer 14 may constitute a light-emitting element EL.

The encapsulation layer 20 may be disposed on the light-emitting elements EL. The encapsulation layer 20 may encapsulate the light-emitting elements EL and prevent moisture or the like from being introduced from the outside into the light-emitting elements EL.

In an embodiment, the encapsulation layer 20 may be implemented by thin layer encapsulation, and may include one or more organic layers and one or more inorganic layers. In an embodiment, the encapsulation layer 20 may include a first inorganic layer 21 disposed on the second electrode 15, an organic layer 22 disposed on the first inorganic layer 21, and a second inorganic layer 23 disposed on the organic layer 22, for example.

The first inorganic layer 21 may prevent moisture, oxygen, or the like, from permeating into the light-emitting elements EL. The first inorganic layer 21 may include or consist of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), or the like.

The organic layer 22 may be disposed on the first inorganic layer 21. The organic layer 22 may improve flatness. The organic layer 22 may include or consist of a liquid organic material, e.g., an acrylic resin, a methacrylic resin, polyisoprene, a vinyl-based resin, an epoxy-based resin, a urethane-based resin, a cellulose-based resin, a perylene-based resin, or the like. Such an organic material may be provided onto the base substrate 11 through deposition, printing, and coating and may be subjected to a curing process.

The second inorganic layer 23 may be disposed on the organic layer 22. The second inorganic layer 23 may perform a role that is substantially the same as or similar to that of the first inorganic layer 21, and may include or consist of a material that is substantially the same as or similar to that of the first inorganic layer 21. The second inorganic layer 23 may completely cover the organic layer 22. In some embodiments, the second inorganic layer 23 and the first inorganic layer 21 may contact each other in the non-display area NDA to form an inorganic-inorganic junction. However, a structure of the encapsulation layer 20 is not limited thereto, and a stacked structure of the encapsulation layer 20 may be variously changed. In an alternative embodiment, in another embodiment, the encapsulation layer 20 may be formed as a glass substrate or the like.

A touch sensor 40 may be disposed on the encapsulation layer 20. In an embodiment, the touch sensor 40 may be disposed directly on the encapsulation layer 20. That is, the encapsulation layer 20 may function as a base part of the touch sensor 40.

The touch sensor 40 may include a touch element layer 41 and a protective layer 43. The touch element layer 41 may include a touch electrode, a touch signal line connected to the touch electrode, or the like. In an embodiment, the touch electrode may include a metal and may have a mesh shape. That is, the touch electrode may include or consist of a metal mesh pattern, and accordingly, flexibility of the touch element layer 41 may be improved.

The protective layer 43 may be disposed on the touch element layer 41 and may protect the touch element layer 41. In an embodiment, the protective layer 43 may include an organic material, and may include or consist of an acrylic polymer, for example. When the protective layer 43 includes or consists of the organic material, flexibility of the touch sensor 40 may be improved.

Referring back to FIGS. 3 and 4, the front stacked structure 200 may be disposed in front of the display panel 100. The front stacked structure 200 may include an impact absorbing layer 230, a cover window 220, and a first composite member 400 that are sequentially stacked forward from the display panel 100.

The impact absorbing layer 230 may serve to protect a structure such as the display panel disposed therebelow from external impact. In an embodiment, the impact absorbing layer 230 may be a polymer layer. The polymer layer may include at least one of PET, PEN, PES, PI, PAR, PC, polymethyl methacrylate (“PMMA”), or a cycloolefin copolymer (“COC”) resin, for example.

In some embodiments, a polarizing member may be included instead of the impact absorbing layer 230. The polarizing member may polarize light passing therethrough. The polarizing member may serve to decrease external light reflection. In an embodiment, the polarizing member may be a polarizing film. The polarizing film may include a polarizing layer and protective substrates sandwiching the polarizing layer on and beneath the polarizing layer. The polarizing layer may include a polyvinyl alcohol film. The polarizing layer may be stretched in one direction. A stretching direction of the polarizing layer may be an absorption axis, and a direction perpendicular to the absorption axis may be a transmission axis. The protective substrates may be disposed on one surface and the other surface of the polarizing layer, respectively. The protective substrate may include or consist of a cellulose resin such as tri-acetyl cellulose (“TAC”), a polyester resin, or the like, but is not limited thereto.

The cover window 220 may be disposed in front of the impact absorbing layer 230. The cover window 220 serves to protect the display panel 100. The cover window 220 may include or consist of a transparent material. The cover window 220 may include glass or plastic, for example.

When the cover window 220 includes the glass, the glass may be ultra thin glass (“UTG”) or thin glass. The ultra thin glass (“UTG”) may be strengthened to have a predetermined stress profile therein. The strengthened ultra thin glass (“UTG”) is more resistant to occurrence of cracks, propagation of the cracks, damage, or the like, due to external impact than before being strengthened. The ultra thin glass (“UTG”) strengthened through a strengthening process may have various stresses for each area.

When the glass is the ultra thin glass (“UTG”) or the thin glass, the glass may have flexible characteristics to have characteristics that it may be bent, folded, or rolled. A thickness of the glass may be in the range of about 10 micrometers (μm) to about 300 μm, for example, and specifically, glass having a thickness of about 10 μm to about 100 μm or about 50 μm may be applied. The glass of the cover window 220 may include soda lime glass, alkali aluminosilicate glass, borosilicate glass, or lithium aluminosilicate glass. The glass of the cover window 220 may include chemically strengthened or thermally strengthened glass in order to have relatively high strength. Chemical strengthening may be achieved through an ion exchange treatment process in an alkali salt. The ion exchange treatment process may be performed twice or more. In addition, the cover window 220 may be formed by coating both surfaces of a polymer film with thin glass.

Referring back to FIGS. 3 and 4, it may be more advantageous in exhibiting flexible

characteristics such as folding that the cover window 220 includes the plastic. In embodiments, the plastic that may be applied to the cover window 220 may include, but are not limited to, polyimide, polyacrylate, PMMA, PC, PEN, polyvinylidene chloride, polyvinylidene difluoride (“PVDF”), polystyrene, an ethylene vinylalcohol copolymer, PES, PEI, PPS, polyallylate, TAC, CAP, or the like. The plastic cover window 220 may include one or more of the plastic materials described above.

The first composite member 400 may be disposed in front of the cover window 220. The first composite member 400 may perform at least one of a scattering prevention function of the cover window 220, an impact absorption function, a chopping prevention function, a fingerprint prevention function, and a glare prevention function. A detailed description of the first composite member 400 will be provided later.

The front stacked structure 200 may include front coupling members 251 and 252 coupling respective members stacked adjacent to each other to each other. In an embodiment, a first coupling member 251 may be disposed between the cover window 220 and the impact absorbing layer 230 to couple the cover window 220 and the impact absorbing layer 230 to each other, and a second coupling member 252 may be disposed between the impact absorbing layer 230 and the display panel 100 to couple the impact absorbing layer 230 and the display panel 100 to each other, for example. That is, the front coupling members 251 and 252 are members attaching layers to one surface of the display panel 100, the first coupling member 251 may be a window coupling member attaching the cover window 220, and the second coupling member 252 may be an impact absorbing layer coupling member attaching the impact absorbing layer 230. Both the front coupling members 251 and 252 may be optically transparent.

The rear stacked structure 300 is disposed behind the display panel 100. The rear stacked structure 300 may include a polymer film layer 310, a cushion layer 320, and a plate 330 that are sequentially stacked backward from the display panel 100.

The polymer film layer 310 may include a polymer film. The polymer film layer 310 may include PI, PET, PC, polyethylene (“PE”), polypropylene (“PP”), polysulfone (“PSF”), PMMA, TAC, a cycloolefin polymer (“COP”), or the like, for example. The polymer film layer 310 may include a functional layer on at least one surface thereof. The functional layer may include a light absorbing layer, for example. The light absorbing layer may include a light absorbing material such as a black pigment or dye. The light absorbing layer includes or consists of black ink, and may be formed on the polymer film by coating or printing.

The cushion layer 320 may be disposed behind the polymer film layer 310. The

cushion layer 320 may serve to prevent the display panel 100 from being damaged by absorbing external impact. The cushion layer 320 may be formed as a single layer or a plurality of stacked films. The cushion layer 320 may include a material having elasticity, such as a polyurethane or PE resin, for example. In an embodiment, the cushion layer 320 may include or consist of a foam material similar to a sponge.

The plate 330 may be disposed behind the cushion layer 320. The plate 330 may be a support member for coupling the display device 10 to a case. The plate 330 may include a material having rigidity. In an embodiment, the plate 330 may include or consist of a metal alloy such as stainless steel (“SUS”) or a single metal.

The plate 330 may be separated based on the folding area FDA in order to allow the display device 10 to be smoothly folded as illustrated in FIGS. 3 and 4, but is not limited thereto. In an embodiment, a first plate may be disposed in the first non-folding area NFA1, and a second plate may be disposed in the second non-folding area NFA2, for example. The first plate and the second plate may be physically spaced apart from each other around the folding area FDA.

The rear stacked structure 300 may include rear coupling members 351 to 353 coupling respective members stacked adjacent to each other to each other. In an embodiment, a third coupling member 351 may be disposed between the display panel 100 and the polymer film layer 310 to couple the display panel 100 and the polymer film layer 310 to each other, a fourth coupling member 352 may be disposed between the polymer film layer 310 and the cushion layer 320 to couple the polymer film layer 310 and the cushion layer 320 to each other, and a fifth coupling member 353 may be disposed between the cushion layer 320 and the plate 330 to couple the cushion layer 320 and the plate 330 to each other, for example. That is, the rear coupling members 351 to 353 are members attaching layers to the other surface of the display panel 100, the third coupling member 351 may be a polymer film coupling member attaching the polymer film layer 310, the fourth coupling member 352 may be a cushion layer coupling member attaching the cushion layer 320, and the fifth coupling member 353 may be a plate coupling member attaching the plate 330. When the plate 330 is separated around the folding area FDA, the fifth coupling member 353 may also be separated in the same shape, but may also be connected as one member without being separated for each of the non-folding areas NFA1 and NFA2, as illustrated in FIG. 3.

When the display device 10 displays an image only on the front surface, the rear coupling members 351 to 353 are not necessarily optically transparent, unlike the front coupling members 251 and 252.

Each of the front coupling members 251 and 252 and rear coupling members 351 to

353 described above may include an adhesive material. The respective coupling members may include an optical clear resin (“OCR”). The respective coupling members may all have the same composition, but may also have different compositions according to their positions and objects to be coupled.

Each of the first to fifth coupling members 251 and 252 and 351 to 353 may have a thickness of about 300 μm or less. In an embodiment, all of the coupling members 251 and 252 and 351 to 353 may have a thickness of about 200 μm or less, and at least some of the coupling members 251 and 252 and 351 to 353 may have a thickness of about 100 μm or less. A lower limit of the thickness of each of the coupling members 251 and 252 and 351 to 353 is not limited, but may be about 10 μm or more in order to exhibit minimal adhesive strength. In an embodiment, each of the first to fifth coupling members 251 and 252 and 351 to 353 may have a thickness of about 25 μm to about 100 μm. Each of the first to fifth coupling members 251 and 252 and 351 to 353 may have the thickness of about 25 μm to about 100 μm to prevent occurrence of separation between components included in the display device when the display device is folded.

Each of the coupling members 251 and 252 and 351 to 353 may be formed as a single adhesive layer, may be formed as a plurality of stacked adhesive layers, or may include adhesive layers on one surface and the other surface of a substrate, such as a double-sided tape.

The display device described above is a foldable display device, and the first composite member 400 may serve to relieve flexuosity and stress of the display device. It is advantageous that the coupling members have a relatively low storage modulus in order to minimize stress when the display device 10 is folded. In addition, the display device 10 is desired to have impact resistance characteristics so as to be capable of withstanding external impact when the external impact is applied to the display device 10. In particular, the first composite member 400 exposed to the outside of the display device 10 should have impact resistance characteristics.

In an embodiment, the display device 10 may include the first composite member 400 that may have a coefficient of thermal expansion, a storage modulus, and impact resistance characteristics so as to be easily used in the foldable display device.

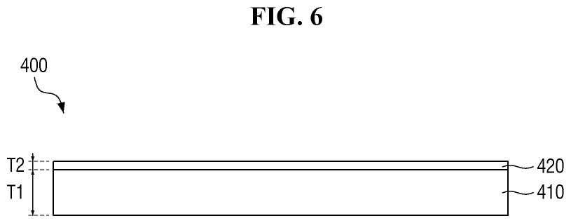

FIG. 6 is a cross-sectional view illustrating an embodiment of a first composite member.

Referring to FIG. 6, the first composite member 400 in an embodiment may include a base layer 410 and a resin layer 420 disposed on one surface of the base layer 410.

The base layer 410 may support the first composite member 400, and may perform at least one of a scattering prevention function of the cover window 220, an impact absorption function, a chopping prevention function, a fingerprint prevention function, and a glare prevention function. The base layer 410 may include a transparent polymer film. In an embodiment, the transparent polymer film may include at least one of PET, PEN, PES, PI, PAR, PC, PMMA, or a COC resin, for example. In an embodiment, the base layer 410 may include or consist of the PET having a predetermined rigidity to have relatively low deformation.

The base layer 410 may be formed to have a predetermined thickness in consideration of impact resistance characteristics and flexuosity and stress when the display device is folded. A thickness T1 of the base layer 410 may be about 100 μm or less. In an embodiment, the thickness T1 of the base layer 410 may be about 80 μm or less. Preferably, the thickness T1 of the base layer 410 may be about 65 μm to about 75 μm.

The resin layer 420 may be a layer for adhering the base layer 410 to the cover window 220. The resin layer 420 may include a resin that is transparent and adhesive. In an embodiment, the resin layer 420 may include at least one of a silicone-based resin, an acrylate-based resin, or a urethane-based resin. In an embodiment, the silicone-based resin may include a siloxane-based resin, for example. In an embodiment, the resin layer 420 may include or consist of a siloxane-based resin.

The resin layer 420 may be formed to have a predetermined thickness in

consideration of impact resistance characteristics and flexuosity and stress when the display device is folded. A thickness T2 of the resin layer 420 may be about 35 μm or less in consideration of an increase in a coefficient of thermal expansion of the first composite member 400. Preferably, the thickness T2 of the resin layer 420 may be about 20 μm to about 35 μm.

The first composite member 400 may have a coefficient of thermal expansion within a predetermined range. The coefficient of thermal expansion may act as a factor determining whether or not cracks have occurred in the first composite member 400 when the display device is folded. When the coefficient of thermal expansion is high, cracks occur in the first composite member 400 when the display device is folded at a relatively low temperature, such that folding reliability may be deteriorated. In an embodiment, the coefficient of thermal expansion of the first composite member 400 may be about 20 ppm/° C. to about 45 ppm/° C. The coefficient of thermal expansion of the first composite member 400 was measured using methods of Experimental Examples to be described later, and was measured, e.g., in a temperature range of about −40° C. to about 60° C. When the coefficient of thermal expansion of the first composite member 400 is about 20 ppm/° C. or more, a folding property of the first composite member 400 may be improved, and when the coefficient of thermal expansion of the first composite member 400 is about 45 ppm/° C. or less, the occurrence of the cracks in the first composite member 400 when the display device is folded at a relatively low temperature may be prevented.

The first composite member 400 may have physical properties such as a storage modulus, a loss modulus, and a loss factor. When members attached to the foldable display device has a relatively high storage modulus, a relatively low loss modulus, and a relatively low loss factor, stress when the display device is folded may be relieved. In an embodiment, the storage modulus of the first composite member 400 may be about 2 GPa to about 3.5 GPa. In addition, when temperature dependency of the storage modulus of the members attached to the foldable display device is low, stress due to a temperature change may be relieved. In an embodiment, the storage modulus of the first composite member 400 may be in the range of about 3.0 GPa to about 3.5 GPa under a temperature condition of about −20° C.

In addition, the storage modulus of the first composite member 400 may be in the range of about 2.5 GPa to about 3.0 GPa under a temperature condition of about 60° C., and may be in the range of about 2 GPa to about 2.5 GPa under a temperature condition of about 80° C. The storage modulus of the first composite member 400 may be in the range of about 2.7 GPa to about 2.9 GPa under a temperature condition of about 25° C. similar to a temperature condition in which the display device is actually used.

The loss modulus of the first composite member 400 may be about 0.04 to about 0.12. Specifically, the loss modulus of the first composite member 400 may be in the range of about 0.10 GPa to about 0.12 GPa under the temperature condition of about −20° C., may be in the range of about 0.04 GPa to about 0.06 GPa under the temperature condition of about 60° C., and may be in the range of about 0.06 GPa to about 0.08 GPa under the temperature condition of about 80° C. The loss modulus of the first composite member 400 may be in the range of about 0.07 GPa to about 0.09 GPa under the temperature condition of about 25° C. similar to the temperature condition in which the display device is actually used.

A ratio of the storage module to the loss module, that is, a loss factor, of the first composite member 400 may be about 0.011 to about 0.060. Specifically, the loss factor of the first composite member 400 may be about 0.028 to about 0.040 under the temperature condition of about −20° C., may be about 0.013 to about 0.024 under the temperature condition of about 60° C., and may be about 0.024 to about 0.045 under the temperature condition of about 80° C. The loss factor of the first composite member 400 may be about 0.024 to about 0.033 under the temperature condition of about 25° C. similar to the temperature condition in which the display device is actually used.

As described above, the first composite member 400 in an embodiment exhibits the storage modulus of about 2.7 GPa to about 2.9 GPa, the loss modulus of about 0.07 GPa to about 0.09 GPa, and the loss factor of about 0.024 to about 0.033 under the temperature condition of about 25° C. similar to the temperature condition in which the display device is actually used, and may thus relieve the stress when the display device is folded, to prevent the occurrence of the cracks and improve the impact resistance characteristics.

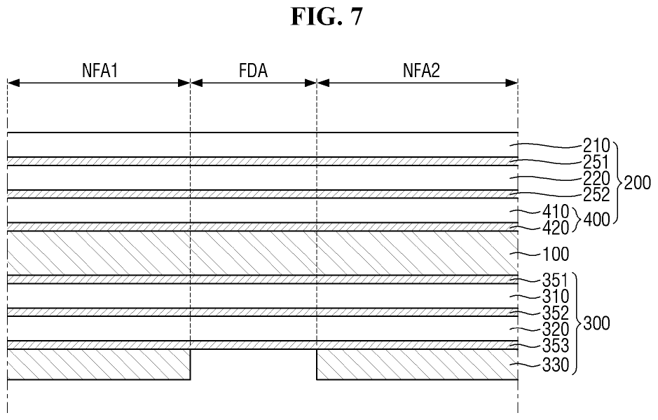

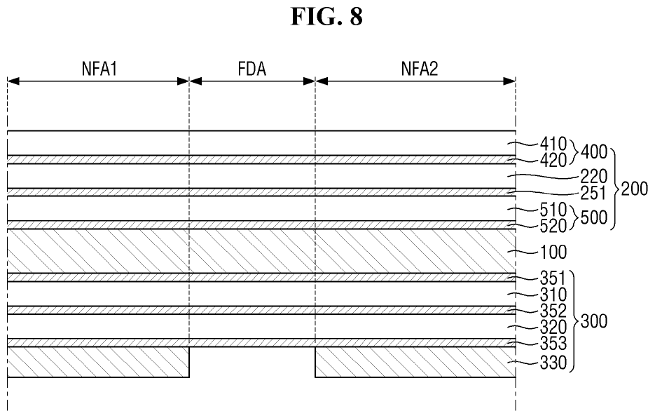

Hereinafter, display devices 10 according to other embodiments will be described. FIGS. 7 and 8 illustrate that the first composite member 400 may be applied to other positions.

FIG. 7 is a cross-sectional view of an embodiment of a display device. FIG. 8 is a cross-sectional view of an embodiment of a display device.

Referring to FIG. 7, in a display device 10 in the illustrated embodiment, the front stacked structure 200 may be disposed in front of the display panel 100. The front stacked structure 200 may include a first composite member 400, a cover window 220, and a cover window protective layer 210 that are sequentially stacked forward from the display panel 100.

The cover window protective layer 210 may perform at least one of a scattering prevention function of the cover window 220, an impact absorption function, a chopping prevention function, a fingerprint prevention function, and a glare prevention function. The cover window protective layer 210 may include a transparent polymer film. The transparent polymer film may include at least one of PET, PEN, PES, PI, PAR, PC, PMMA, or a COC resin.

A first coupling member 251 may be disposed between the cover window protective layer 210 and the cover window 220 to couple the cover window protective layer 210 and the cover window 220 to each other, and a second coupling member 252 may be disposed between the cover window 220 and the first composite member 400 to couple the cover window 220 and the first composite member 400 to each other.

In the illustrated embodiment, the first composite member 400 may be disposed instead of the impact absorbing layer 230 (refer to FIG. 3) described above with reference to FIG. 3. The first composite member 400 may include a base layer 410 and a resin layer 420 disposed on one surface of the base layer 410. The base layer 410 may substitute for the impact absorbing layer by including a transparent polymer film. The resin layer 420 may be disposed between the base layer 410 and the display panel 100 to couple the base layer 410 and the display panel 100 to each other.

Further, referring to FIG. 8, a display device 10 in another embodiment may include a first composite member 400 and a second composite member 500. Specifically, the front stacked structure 200 may include the second composite member 500, a cover window 220, and the first composite member 400 that are sequentially stacked forward from the display panel 100.

The first composite member 400 may be the same as the first composite member 400 (refer to FIG. 3) described above with reference to FIG. 3, and the second composite member 500 may be the same as the first composite member 400 (refer to FIG. 7) described above with reference to FIG. 7.

The first composite member 400 may include a first base layer 410 and a first resin layer 420, and the second composite member 500 may include a second base layer 510 and a second resin layer 520. The first resin layer 420 of the first composite member 400 may be disposed between the first base layer 410 and the cover window 220, and the second resin layer 520 of the second composite member 500 may be disposed between the second base layer 510 and the display panel 100.

Each of the first composite member 400 and the second composite member 500 may have a storage modulus of about 2.7 GPa to about 2.9 GPa at about 25° C. and a coefficient of thermal expansion of about 20 ppm/° C. to about 45 ppm/° C. in a temperature range of about −40° C. to about 60° C. In addition, each of the first composite member 400 and the second composite member 500 may have a loss modulus of about 0.07 GPa to about 0.09 GPa at about 25° C. and a loss modulus of about 0.024 to about 0.033 at about 25° C.

As described above, in the display devices 10 in embodiments, composite members may be variously applied in front of and/or behind the cover window 220. In an embodiment, the composite member may be applied instead of the cover window protective layer and/or the impact absorbing layer, for example. The composite member in an embodiment has the coefficient of thermal expansion, the storage modulus, the loss modulus, and an elastic modulus applicable to the foldable display device, and may thus relieve the stress when the display device 10 is folded, to prevent the occurrence of the cracks and improve the impact resistance characteristics.

Hereinafter, a method of manufacturing the display device described above will be described. The first composite member (also referred to as a composite member) 400 in an embodiment may be manufactured by a simple method to be described below and formed on the cover window 220 of the display device 10. Hereinafter, processes of manufacturing the composite member 400 will be mainly described, and a material or a thickness of the composite member 400 has been described above, and a description thereof will thus be omitted.

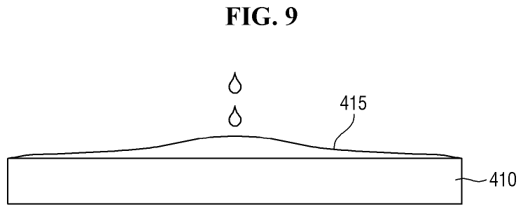

FIGS. 9 to 11 are cross-sectional views illustrating an embodiment of processes of a method of manufacturing the display device.

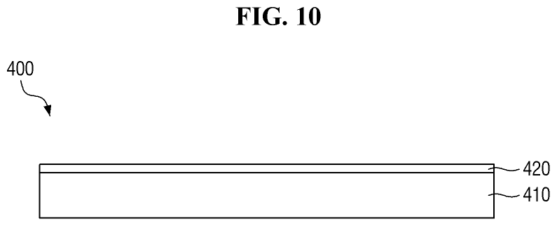

Referring to FIGS. 9 and 10, the display device 10 in an embodiment may be

manufactured by forming the composite member 400 and coupling the composite member 400 onto the display panel 100.

First, the composite member 400 may be manufactured by preparing the base layer 410 and forming the resin layer 420 on the base layer 410. Specifically, the base layer 410 is prepared, and a resin 415 is applied onto one surface of the base layer 410. The resin 415 may be in a solution state for manufacturing the above-described resin layer 420. The resin 415 may be applied onto the base layer 410 by a solution process such as inkjet printing, slit coating, screen printing, or spin coating. After a process of applying the resin 415, the resin 415 is dried through heat treatment to form the resin layer 420. Accordingly, the composite member 400 in which the resin layer 420 is formed on the base layer 410 may be manufactured.

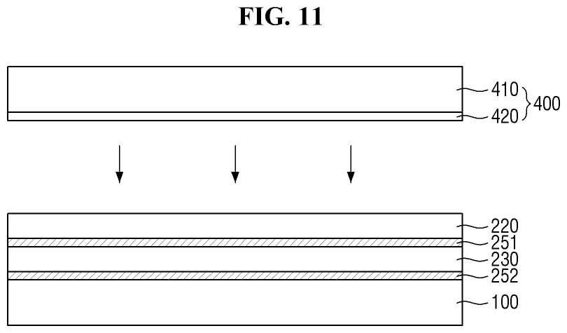

Next, referring to FIG. 11, the display device 10 to which the composite member 400 manufactured as described above is attached is prepared. The display device 10 may be in a state in which the impact absorbing layer 230 and the cover window 220 disposed forward from the display panel 100 may be coupled to each other through the first coupling member 251 and the second coupling member 252. Subsequently, the composite member 400 manufactured as described above is aligned and bonded onto the cover window 220 of the display device 10 to manufacture the display device 10.

In a general display device 10, a layer may be coupled to the front of the display panel 100 using an adhesive such as a pressure sensitive adhesive (“PSA”). A process of using the adhesive may be performed by laminating and adhering an adhesive having a film form onto an adherend and then laminating an adhesive object on the adhesive. However, a lamination process may be performed twice, which may be complicate. In the illustrated embodiment described above, the display device 10 may be simply manufactured by coating the base layer 410, which is an adhesive object, with the resin layer 420 acting as an adhesive to form the composite member and bonding the composite member onto the cover window 220, which is an adherend. Accordingly, manufacturing cost may be reduced and productivity may be improved by simplifying the process.

Hereinafter, the above-described embodiments will be described in more detail through Experimental Examples.

### Experimental Example 1: Measurement of Coefficient of Thermal Expansion of Composite Member

As Comparative Example 1, a single PET film having a thickness of 50 μm was prepared.

As Comparative Example 2, a siloxane-based resin was coated on a PET film having a thickness of 50 μm to form a resin layer having a thickness of 50 μm.

As Comparative Example 3, a siloxane-based resin was coated on a PET film having a thickness of 75 μm to form a resin layer having a thickness of 40 μm.

As Example 1, a siloxane-based resin was coated on a PET film having a thickness of 65 μm to form a resin layer having a thickness of 30 μm.

As Example 2, a siloxane-based resin was coated on a PET film having a thickness of 75 μm to form a resin layer having a thickness of 20 μm.

As Example 3, a siloxane-based resin was coated on a PET film having a thickness of 75 μm to form a resin layer having a thickness of 25 μm.

As Example 4, a siloxane-based resin was coated on a PET film having a thickness of 75 μm to form a resin layer having a thickness of 35 μm.

Three samples each manufactured according to Comparative Examples 1 to 3 and Examples 1 to 4 were prepared, and coefficients of thermal expansion of the samples were then measured by measuring change amounts in a section of −40° C. to 60° C. while raising a temperature from −50° C. to 150° C. at a rate of 10° C. per minute using a thermo mechanical analyzer (TMA). Measurement results of the coefficients of thermal expansion were illustrated in Table 1 (coefficients of thermal expansion are represented in units of ppm/° C.).

TABLE 1

| Sample # | #1 | #2 | #3 | Average Value |
|---|---|---|---|---|
| Comparative | 14.95 | 15.11 | 15.20 | 15.09 |
| Example 1 | | | | |
| Comparative | 65.10 | 58.60 | 43.77 | 55.82 |
| Example 2 | | | | |
| Comparative | 55.9 | 67.8 | 52.6 | 58.7 |
| Example 3 | | | | |
| Example 1 | 42.2 | 35.8 | 37.0 | 38.3 |
| Example 2 | 29.8 | 34.1 | 37.2 | 33.7 |
| Example 3 | 30.02 | 33.46 | 35.45 | 32.98 |
| Example 4 | 39.8 | 43.9 | 45.2 | 42.9 |

### Experimental Example 2: Pen Drop Test and Relatively Low Temperature Folding Test of Display Device

Display device samples as illustrated in FIG. 3 were manufactured by coupling the composite member samples manufactured according to Comparative Examples 1 to 3 and Examples 1 to 4.

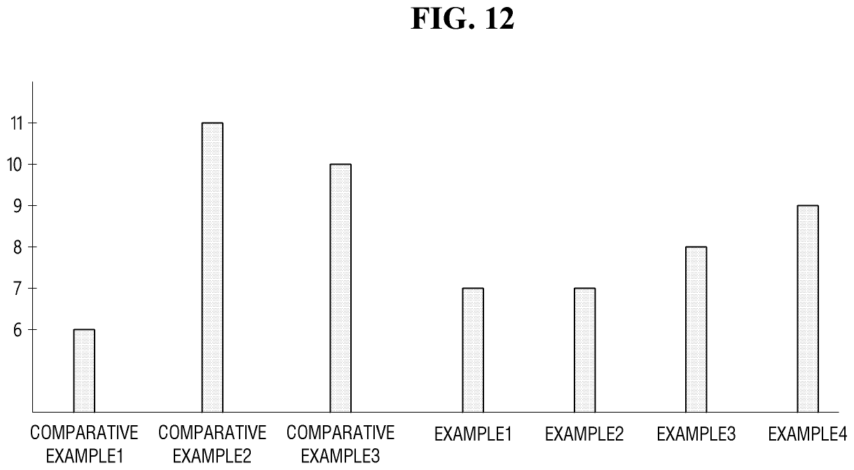

A pen drop test was performed in a manner of dropping a pen having a diameter of 0.7 phi (π) and a weight of 5.35 grams (g) on surfaces of the display device samples fixed onto granite plates and confirming heights at which bright spots occur. The pen drop test was performed in the range of 0.5 centimeter (cm) to 12 cm while moving a drop height of the pen by 0.1 cm. The heights at which the bright spots finally occurred while repeating the drop of the pen were described. Pen drop test results were illustrated in FIG. 12. FIG. 12 is a chart illustrating pen drop test results of display device samples according to Experimental Example 1.

In a relatively low temperature folding test, the display device samples were folded and unfolded 3,000 times under a temperature condition of −20° C., and it was then observed whether or not cracks occurred in the surfaces of the display device samples. When the cracks occurred, it was marked as NG, and when the cracks did not occur, it was marked as OK. Results of the relatively low temperature folding test were illustrated in Table 2.

TABLE 2

| | Test Result |
|---|---|
| Comparative Example 1 | OK |
| Comparative Example 2 | NG |
| Comparative Example 3 | NG |
| Example 1 | OK |
| Example 2 | OK |
| Example 3 | OK |
| Example 4 | OK |

Referring to Tables 1 and 2 and FIG. 12, in the composite member according to Comparative Example 1 and the display device including the same, an average coefficient of thermal expansion was 15.09 ppm/° C., which is low, and cracks did not occur in the folding test, but a pen drop test result was 6 cm, which is low. In the composite member according to Comparative Example 2 and the display device including the same, an average coefficient of thermal expansion was 55.82 ppm/° C., which is high, and a pen drop test result was 11 cm, which is high, but cracks occurred in the folding test. In addition, in the composite member according to Comparative Example 3 and the display device including the same, an average coefficient of thermal expansion was 58.7 ppm/° C., which is high, and a pen drop test result was 10 cm, which is high, but cracks occurred in the folding test.

In a case of Examples 1 to 4, average coefficients of thermal expansion were 38.3 ppm/° C., 33.7 ppm/° C., 32.98 ppm/° C., and 42.9 ppm/° C., pen drop test results were 7 cm to 8 cm, and cracks did not occur in the folding test.

As a result, it could be confirmed that the composite members according to Examples 1 to 4 exhibit coefficients of thermal expansion of 20 ppm/° C. to 45 ppm/° C. and the display devices including such composite members have excellent impact resistance characteristics to show folding test results suitable for being applied to a foldable display device.

### Experimental Example 3: Measurement of Storage Modulus, Loss Modulus, and Loss Factor of Composite Member

Storage moduli and loss moduli of the composite member samples according to Comparative Example 1, Comparative Example 2, and Example 3 manufactured in Experimental Example 1 described above were measured under temperature conditions of −20° C., 25° C., 60° C., and 80° C., loss factors were calculated based on the measured storage moduli and loss moduli, and measurement and calculation results were illustrated in Table 3. The storage moduli and the loss moduli were measured while raising a temperature from −50° C. to 150° C. at a rate of 3° C. per minute using a dynamic mechanical analyzer (“DMA”) (storage moduli and the loss moduli are represented in units of GPa).

TABLE 3

| | | Storage | | |
|---|---|---|---|---|
| | | Modulus | Loss Modulus | Loss Factor |
| −20° C. | Comparative | 3.58 | 0.11 | 0.030 |
| | Example 1 | | | |
| | Comparative | 2.73 | 0.10 | 0.038 |
| | Example 2 | | | |
| | Example 3 | 3.17 | 0.11 | 0.034 |
| 25° C. | Comparative | 3.40 | 0.07 | 0.019 |
| | Example 1 | | | |
| | Comparative | 2.18 | 0.06 | 0.029 |
| | Example 2 | | | |
| | Example 3 | 2.84 | 0.08 | 0.027 |
| 60° C. | Comparative | 3.24 | 0.06 | 0.018 |
| | Example 1 | | | |
| | Comparative | 1.79 | 0.07 | 0.038 |
| | Example 2 | | | |
| | Example 3 | 2.56 | 0.05 | 0.021 |
| 80° C. | Comparative | 3.03 | 0.08 | 0.103 |
| | Example 1 | | | |
| | Comparative | 1.21 | 0.13 | 0.106 |
| | Example 2 | | | |
| | Example 3 | 2.23 | 0.07 | 0.032 |

Referring to Table 3, it may be seen that the composite member according to Example 3 exhibiting excellent characteristics in the pen drop test and the folding test in Experimental Examples 1 and 2 has a storage modulus of 2 GPa to 3.5 GPa, has a loss modulus of 0.04 to 0.12, and has a loss factor of 0.02 to 0.035.

The composite member in an embodiment has physical properties such as the coefficient of thermal expansion, the storage modulus, the loss modulus, and the loss factor described above to have excellent impact resistance characteristics and relieve stress when the display device is folded, and may thus be suitable for being used in the foldable display device.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
a display panel including a surface disposed at a front thereof; and
a front stacked structure disposed on the surface of the display panel, the front stacked structure including
a cover window; and
a first composite member disposed on the cover window, the first composite member including:
a base layer; and
a resin layer disposed on the base layer,
wherein the first composite member has a coefficient of thermal expansion of about 20 parts per million per degrees Celsius to about 45 parts per million per degrees Celsius in a temperature range of about-40 degrees Celsius to about 60 degrees Celsius.

2. The display device of claim 1, wherein the base layer has a thickness of about 65 micrometers to about 75 micrometers.

3. The display device of claim 1, wherein the resin layer includes any one of a silicone-based resin, an acrylate-based resin, and a urethane-based resin.

4. The display device of claim 3, wherein the silicone-based resin includes a siloxane-based resin.

5. The display device of claim 1, wherein the resin layer has a thickness of about 20 micrometers to about 35 micrometers.

6. The display device of claim 1, wherein the first composite member has a storage modulus of about 2.7 gigapascals to about 2.9 gigapascals at about 25 degrees Celsius.

7. The display device of claim 1, wherein the first composite member has a loss modulus of about 0.07 gigapascals to about 0.09 gigapascals at about 25 degrees Celsius.

8. The display device of claim 1, wherein the first composite member has a loss factor of about 0.024 to about 0.033 at about 25 degrees Celsius.

9. The display device of claim 1, wherein the resin layer is disposed between the cover window and the base layer and couples the cover window and the base layer to each other.

10. The display device of claim 1, wherein the front stacked structure further includes:
an impact absorbing layer disposed between the display panel and the cover window;
a first coupling member disposed between the cover window and the impact absorbing layer; and
a second coupling member disposed between the impact absorbing layer and the display panel.

11. The display device of claim 1, wherein the display panel includes an opposite surface disposed at a rear thereof, and
the display device further comprises a rear stacked structure disposed on the opposite surface of the display panel, and
the rear stacked structure includes a polymer film layer disposed behind the display panel, a cushion layer disposed behind the polymer film layer, and a plate disposed behind the cushion layer.

12. A display device comprising:
a display panel including a surface disposed at a front thereof; and
a front stacked structure disposed on the surface of the display panel,
wherein the front stacked structure includes a cover window, a first composite member disposed on the cover window, and a second composite member disposed between the cover window and the display panel,
each of the first composite member and the second composite member includes a base layer and a resin layer disposed on the base layer, and
each of the first composite member and the second composite member has a storage modulus of about 2.7 gigapascals to about 2.9 gigapascals at about 25 degrees Celsius.

13. The display device of claim 12, wherein the base layer has a thickness of about 65 micrometers to about 75 micrometers.

14. The display device of claim 12, wherein the resin layer includes any one of a silicone-based resin, an acrylate-based resin, and a urethane-based resin.

15. The display device of claim 14, wherein the silicone-based resin includes a siloxane-based resin.

16. The display device of claim 12, wherein the resin layer has a thickness of about 20 micrometers to about 35 micrometers.

17. The display device of claim 12, wherein each of the first composite member and the second composite member has a coefficient of thermal expansion of about 20 parts per million per degrees Celsius to about 45 parts per million per degrees Celsius in a temperature range of about-40 degrees Celsius to about 60 degrees Celsius.

18. The display device of claim 12, wherein each of the first composite member and the second composite member has a loss modulus of about 0.07 gigapascals to about 0.09 gigapascals at about 25 degrees Celsius.

19. The display device of claim 12, wherein each of the first composite member and the second composite member has a loss factor of about 0.024 to about 0.033 at about 25 degrees Celsius.

20. The display device of claim 12, wherein the resin layer of the first composite member is disposed between the cover window and the base layer of the first composite member, and the resin layer of the second composite member is disposed between the display panel and the base layer of the second composite member.
